(19) United States
(12) Patent Application Publication
(10) Pub. No.: US 2021/0172784 A1
(43) Pub. Date: Jun. 10, 2021

(54) LIQUID SOURCE VAPORIZATION APPARATUS

(71) Applicant: HORIBA STEC, Co., Ltd., Kyoto-shi (JP)

(72) Inventors: Tadayuki NAGANO, Kyoto-shi (JP); Takao WATANABE, Kyoto-shi (JP)

(21) Appl. No.: 17/108,814

(22) Filed: Dec. 1, 2020

(30) Foreign Application Priority Data
Dec. 4, 2019 (JP) 2019-219440

(51) Int. Cl. G01F 23/24; G01F 25/00; B01B 1/00

(52) U.S. Cl. CPC G01F 23/241; H05B 1/0244; B01B 1/005; G01F 25/0061

(57) ABSTRACT

The liquid source vaporization apparatus comprises a tank inside of which a liquid source is stored, a heater that applies heat to the liquid source in the tank, a plurality of liquid surface detecting bodies wherein each of liquid surface detecting points is arranged in a predetermined height range in the tank with a set height regarded as the reference, a reference detecting body arranged above the predetermined height range in the tank, and a liquid surface discriminator that discriminates whether or not there is the liquid source at the set height on a basis of a threshold value set based on a change in electrical resistance of the reference detecting body and a change in electrical resistance of a plurality of the liquid surface detecting bodies.

### TECHNICAL FIELD

The present invention relates to a liquid source vaporization apparatus used for vaporizing a liquid source.

### BACKGROUND ART

For example, in a semiconductor manufacturing process, a material gas made by vaporizing a liquid source is supplied to a chamber. As shown in the patent document 1, a liquid source vaporization apparatus that generates a material gas comprises a tank inside of which a liquid source is stored and a heater arranged to cover an outside of the tank, and the liquid source in the tank is heated to vaporize and derived to the outside of the tank.

For the liquid source vaporization apparatus, the liquid source is replenished in the tank as appropriate to compensate for the decrease in the liquid source due to vaporization of the liquid source. Furthermore, it is necessary to keep the liquid surface of the liquid source in the tank at the upper limit of the liquid surface in order to prevent the amount of the liquid source in the tank from becoming excessive due to replenishment and the liquid source being supplied to the chamber in a liquid state without being vaporized.

For this purpose, a liquid surface detecting body made of platinum or the like is arranged in the tank to detect whether or not the liquid source is at the upper limit of the liquid surface. For example, a constant voltage is applied to the liquid surface detecting body and a current output by the liquid surface detecting body is monitored. In case that the liquid surface detecting body is in the liquid source, the heat is dissipated to a greater extent than in the gas phase, resulting in drop in temperature. As a result of this, the electrical resistance of the liquid surface detecting body is decreased and the output current is increased. Therefore, it is possible to detect whether or not there is the liquid source on a basis of the magnitude of the monitored current.

However, with the liquid surface detection method described above, when the liquid source boils, bounces up and adheres to the liquid surface detecting body, which may cause the liquid surface detecting body to misinterpret the presence of the liquid source even though there is actually no liquid source at the upper limit of the liquid surface. In addition, changes in the pressure and the temperature inside the tank can also affect the output by the liquid surface detecting body, causing a false reading.

### PRIOR ART DOCUMENT

### Patent Document

Patent document 1 Japanese Examined Patent Application Publication No. 6212467

### SUMMARY OF THE INVENTION

### Problem to be Solved by the Invention

The present invention has been made in view of the above-mentioned problems, and is intended to provide a liquid source vaporization apparatus that is unlikely to cause false detection of a liquid surface even though, for example, a boiling phenomenon occurs in a liquid source or the surrounding environmental conditions are greatly changed.

### Means for Solving the Problem

More specifically, the liquid source vaporization apparatus in accordance with the present invention is characterized by comprising a tank inside of which a liquid source is stored, a heater that applies heat to the liquid source in the tank, a plurality of liquid surface detecting bodies each of whose liquid surface detecting points is arranged in a predetermined height range in the tank with a set height regarded as the reference, a reference detecting body arranged above the predetermined height range in the tank, and a liquid surface discriminator that discriminates whether or not there is the liquid source at the set height on a basis of a threshold value set based on a change in electrical resistance of the reference detecting body and a change in electrical resistance of a plurality of the liquid surface detecting bodies.

In accordance with this arrangement, since the reference detecting body is arranged above the predetermined height range, even though the liquid source boils, bounces up and adheres to any of the liquid surface detecting bodies in a state that the liquid surface of the liquid source is lower than each of the liquid surface detecting points, it is possible not to make the liquid source adhere to the reference detecting body. Accordingly, since it is possible to keep a state wherein the reference detecting body is exposed only to a material gas that is the vaporized liquid source in the tank, it is possible to make electric resistance of the reference detecting body affected only by the temperature and the pressure in the tank. Therefore, the threshold value set based on the change in the electrical resistance of the reference detecting body can reflect only the change in the temperature or the pressure of the material gas in the tank. In addition, since the liquid surface discriminator discriminates whether or not there is the liquid source at the liquid surface detecting point on a basis of the threshold value reflecting the pressure and the temperature in the tank, it is possible to make the liquid surface discriminator less prone to misjudgment than a conventional liquid surface discriminator.

Furthermore, since the liquid surface discriminator discriminates whether or not there is the liquid source at the liquid surface detecting point on a basis of the change in the electric resistance of a plurality of the liquid surface detecting bodies, if the discriminated result is discriminated to be correct, for example, only when the discriminated result based on each of the liquid surface detecting bodies is that there is the liquid source at the liquid surface detecting point, it is possible to prevent misjudgment due to bouncing up of the liquid source.

In order to make it possible to electrically detect the change in the resistance due to the change of a heat dissipating state when the liquid source contacts the plurality of the liquid surface detecting bodies and to discriminate whether or not there is the liquid source at the set height based on the change of the output signal, the liquid surface discriminator may comprise a constant voltage circuit that applies a constant voltage to each of the plurality of the liquid surface detecting bodies and the reference detecting body respectively, a current measurement mechanism that measures each of currents output by the plurality of the liquid surface detecting bodies and a current of the reference detecting body respectively, a threshold current setting part that sets a threshold current on a basis of the current output by the reference detecting body, and a discriminating part that discriminates whether or not there is the liquid source at the set height by comparing each of the currents output by the plurality of the liquid surface detecting bodies with the threshold current.

For example, in order to ensure that the liquid source is not mistakenly discriminated to be at the set height even if the liquid source boils up and droplets adheres to some of the plurality of the liquid surface detecting bodies, the discriminating part may discriminate that there is the liquid surface of the liquid source at the set height in case that all of the currents output by the plurality of the liquid surface detecting bodies exceed the threshold current.

A concrete mode for preventing misjudgments regarding detection of the liquid surface from occurring even if the pressure or the temperature in the tank changes is represented by that the threshold current setting part sets the threshold current so as to be set that the bigger the current output by the reference detecting body is, the bigger the threshold current value is.

In order to make it possible not to damage reliability of the discriminated result of the liquid surface discriminator by making it possible to diagnose that any one of the plurality of the liquid surface detecting bodies is in a state of being unable to determine whether or not there is the liquid source at the liquid surface detecting point, the liquid surface detecting points of the plurality of the liquid surface detecting bodies may be set at the same height in the tank, and the liquid source vaporization apparatus may further comprise an abnormality diagnosing part that specifies the liquid surface detecting body that is experiencing an abnormality based on the currents output by the plurality of the liquid surface detecting bodies.

As a concrete mode of the liquid source vaporization apparatus in accordance with this invention for discriminating whether or not there is the liquid source at the set height on a basis of the voltage represented is that the liquid surface discriminator comprises a constant current circuit that applies a constant current to each of the plurality of the liquid surface detecting bodies and the reference detecting body respectively, a voltage measurement mechanism that measures each of voltages output by the plurality of the liquid surface detecting bodies and a voltage of the reference detecting body respectively, a threshold voltage setting part that sets a threshold voltage on a basis of the voltage output by the reference detecting body, and a discriminating part that discriminates whether or not there is the liquid source at the set height by comparing each of the voltages output by the plurality of the liquid surface detecting bodies with the threshold voltage.

### Effect of the Invention

In accordance with the liquid source vaporization apparatus of this invention, since the liquid source vaporization apparatus comprises a plurality of the liquid surface detecting bodies each of whose liquid surface detecting points is arranged in the predetermined height range in the tank with the set height regarded as the reference, even though the liquid source bounces up due to boiling of the liquid source and adheres to any of the liquid surface detecting bodies, it is possible to avoid a misjudgment on a basis of the change in the electric resistor of the other liquid surface detecting body. In addition, since the reference detecting body arranged above the predetermined height range is not affected by the bouncing up of the liquid source and is affected by only the change of the pressure or the temperature in the tank, the threshold value set on a basis of the change in the electric resistance of the reference detecting body can be also affected by only the pressure or the temperature in the tank. Accordingly, it is possible to avoid a misjudgment of the liquid surface detection due to the state change in the tank.

### BRIEF DESCRIPTION OF THE DRAWINGS

FIG. 1 is a schematic diagram showing an overall configuration of a liquid source vaporization apparatus in one embodiment of the present claimed invention.

FIG. 2 is a schematic diagram showing details of a tank, a liquid surface detecting body and a reference detecting body in accordance with this embodiment.

FIG. 3 is a schematic graph showing an example of detecting the liquid surface of a liquid source in a state of a constant pressure and a constant temperature in accordance with this embodiment.

FIG. 4 is a schematic graph showing an example of detecting the liquid surface of the liquid source in a state wherein the pressure is changing in accordance with this embodiment.

FIG. 5 is a schematic graph showing an example of detecting the liquid surface of the liquid source in a state wherein the temperature is changing in accordance with this embodiment.

FIG. 6 is a schematic graph showing an example of detecting the liquid surface of the liquid source in a state of a constant pressure and a constant pressure in accordance with another embodiment of the present claimed invention.

### BEST MODE OF EMBODYING THE INVENTION

A liquid source vaporization apparatus 100 according to one embodiment of the present claimed invention will be described with reference to each drawing.

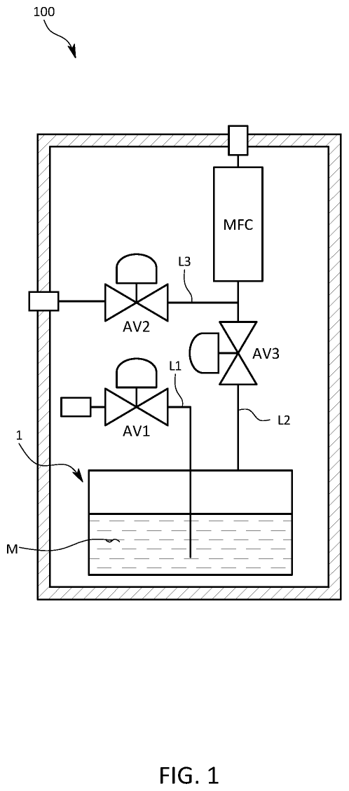

The liquid source vaporization apparatus 100 in accordance with this embodiment generates various gases to be supplied to a chamber in, for example, a semiconductor manufacturing process. As shown in FIG. 1, the liquid source vaporization apparatus 100 comprises a tank 1 inside of which a liquid source (M) is stored, an introducing line L1 that introduces the liquid source (M) into the tank 1, a discharging line L2 that discharges a material gas generated by vaporizing the liquid source (M) in the tank 1, and a dilution line (L3) that introduces a diluted gas into the discharging line L2.

The introducing line L1 is so arranged with its distal end arranged near a bottom surface of the tank 1, and the liquid source (M) is replenished from the introducing line L1 to the tank 1 at, for example, a predetermined interval. At this time, the amount of the replenished liquid source (M) is controlled so that the liquid source (M) reaches a predetermined liquid surface in the tank 1. A liquid surface detection mechanism (LD) is provided in the tank 1 to detect whether or not the liquid surface of the liquid source (M) is at the upper limit of the liquid surface as described later. The discharging line L2 is communicated with an upper surface of the tank 1, and a mass flow controller (MFC) as being a flow rate controller that controls a flow rate of a mixed gas comprising the material gas and a dilution gas is provided on the discharging line L2.

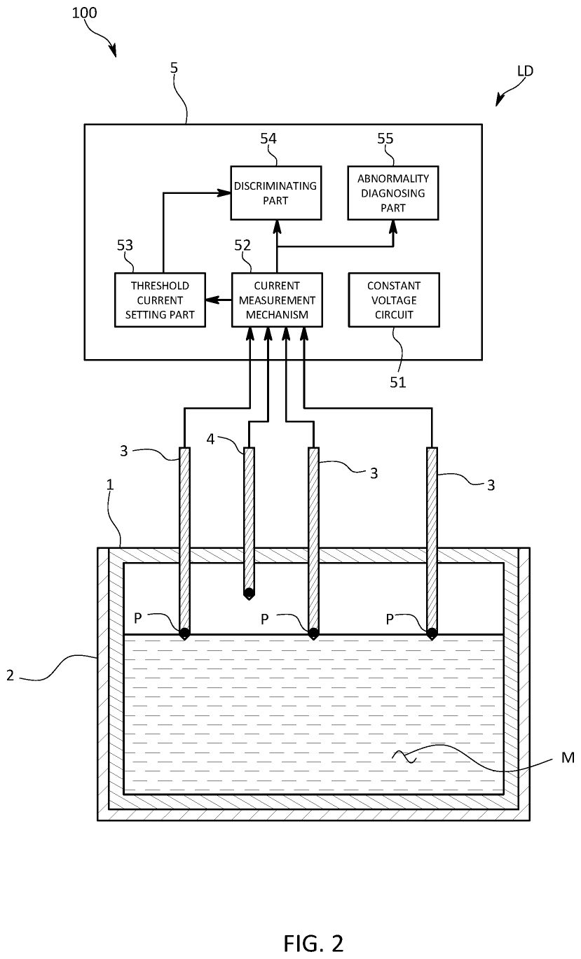

Next, the tank 1 and the liquid surface detection mechanism (LD) will be described in detail with reference to FIG. 2.

The tank 1 has a generally rectangular hollow shape and is configured so that a predetermined volume or more of the material gas exists on the upper side in the tank 1. A heater 2 is provided on the outer surface of the tank 1. The heater 2 is temperature controlled so that the temperature in the tank 1 is equal to or higher than a vaporization temperature of the liquid source (M). The tank 1 is not limited to the above-mentioned shape, and the tank 1 may have a hollow cylinder shape.

The liquid surface detection mechanism (LD) comprises a plurality of liquid surface detecting bodies 3 arranged in the tank 1, a reference detecting body 4 arranged above the liquid surface detecting bodies 3 in the tank 1, and a liquid surface discriminator 5 that discriminates whether or not the liquid surface of the liquid source (M) exists at the upper limit of the liquid surface as being a set height based on output signals obtained from the liquid surface detecting bodies 3 and the reference detecting body 4.

A plurality of the rod-shaped liquid surface detecting bodies 3 made of, for example, platinum (Pt) are arranged in the tank 1. In this embodiment, each distal end as being a liquid surface detecting point (P) of each of the liquid surface detecting bodies 3 is arranged in a predetermined range of heights within the tank 1 with a set height regarded as the reference and is arranged at substantially the same height (level). Concretely, the liquid surface detecting point (P) of each of the liquid surface detecting bodies 3 is located at the upper limit of the liquid surface where the liquid source (M) does not come out of the discharging line L2 still in a liquid state. Although the liquid surface detecting points (P) of the liquid surface detecting bodies 3 are mounted so that they are aligned at the upper limit of the liquid surface as being the set height in this embodiment, the liquid surface detecting points (P) may be mounted at various heights within a predetermined range of the heights based on the set height as the reference due to mounting errors or the like. Preferably, the liquid surface detecting point (P) may be located within a range of 5 mm in the vertical direction based on the set height as the reference. The set height may be set at a liquid surface lowered by multiplying the upper limit of the liquid surface by a predetermined safety factor to provide a safety margin.

Whether or not the liquid source (M) is in contact with the liquid surface detecting point (P) of each of the liquid surface detecting bodies 3 is detected based on the change in electrical resistance of the liquid surface detecting bodies 3. In this embodiment, a constant voltage is applied to the liquid surface detecting bodies 3 by the liquid surface discriminator 5, and the liquid surface detecting bodies 3 are kept in a state of generating heat. Since an amount of heat dissipation of the liquid surface detecting bodies 3 is greater in case that the liquid surface detecting bodies 3 are in contact with the liquid source (M) than in case that the liquid surface detecting bodies 3 are not in contact with the liquid source (M), the electrical resistance of the liquid surface detecting bodies 3 is lowered. As a result of this, it is possible to determine whether or not the liquid source (M) exists at the liquid surface detecting point (P) based on whether or not the current value output by each of the liquid surface detecting bodies 3 is greater than or equal to the threshold current.

In this embodiment, three liquid surface detecting bodies 3 are provided in the tank 1, and each of the three liquid surface detecting bodies 3 is arranged approximately evenly spaced with respect to the horizontal direction. Since the heater 2 applies heat to the inside of the tank 1 from the outside thereof, the temperature inside the tank 1 tends to be higher than the temperature outside. In consideration of this, at least one of the three liquid surface detecting bodies 3 is arranged in a center part in the tank 1 in this embodiment, and the other liquid surface detecting bodies 3 are arranged in an outer circumferential side in the tank 1. With this arrangement, even though the liquid source (M) partially boils in the tank 1, it is possible to prevent the liquid source (M) from bouncing and sticking to all of the liquid surface detecting bodies 3.

The reference detecting body 4 is rod-shaped made of platinum similar to the liquid surface detecting bodies 3, and the constant voltage similar to the liquid surface detecting bodies 3 is applied to the reference detecting body 4 by the liquid surface discriminator 5. In addition, the reference detecting body 4 is arranged to locate only further above the liquid surface detecting point (P) of each of the liquid surface detecting bodies 3. More specifically, the reference detecting body 4 is located only at a height where no liquid source (M) bounces up and adheres to the reference detecting body 4, even though the liquid source (M) in the tank 1 boils in a state wherein the liquid surface of the liquid source (M) in the tank 1 is at the liquid surface detecting point (P). In other words, the reference detecting body 4 is placed only in the gas phase in the tank 1 on a constant basis. The current value output by this reference detecting body 4 is used to set a threshold current for liquid surface detection of the liquid source (M).

The liquid surface discriminator 5 determines whether or not the liquid source (M) is at the upper limit of the liquid surface as being the set height based on the change in the electrical resistance of the plurality of the liquid surface detecting bodies 3 and the reference detecting body 4. In addition, in case that the liquid surface discriminator 5 determines that the liquid surface of the liquid source (M) is at the upper limit of the liquid surface, the replenishment of the liquid source (M) from the introducing line L1 into the tank 1 is stopped.

More concretely, the liquid surface discriminator 5 realizes its functions by means of a so-called computer equipped with an A/D converter, a D/A converter, a CPU and a memory or the like, programs stored in the memory are executed, and at least functions as a constant voltage circuit 51, a current measurement mechanism 52, a threshold current setting part 53, a discriminating part 54, and an abnormality diagnosing part 55 are produced by cooperatively working each devices.

The constant voltage circuit 51 applies a constant voltage to a plurality of the liquid surface detecting bodies 3 and the reference detecting body 4. The constant voltage is set so that the temperatures of the liquid surface detecting bodies 3 and the reference detecting body 4 are kept slightly higher than the environmental temperature in the tank 1. In FIG. 2, connection between the constant voltage circuit 51 and each of the liquid surface detecting bodies 3 and the reference detecting body 4 is omitted.

The current measurement mechanism 52 measures the current output by the plurality of the liquid surface detecting bodies 3 and the reference detecting body 4 respectively.

The threshold current setting part 53 appropriately sets the threshold current based on the current output by the reference detecting body 4. In this embodiment, the threshold current setting part 53 is so configured to increase the value of the threshold current as the current output by the reference detecting body 4 increases. More specifically, since the reference detecting body 4 is configured so as not to be in contact with the liquid source (M), the electrical resistance changes only under the influence of the pressure of the material gas and the temperature in the tank 1. Therefore, the pressure and the temperature of the material gas can be corrected by setting the threshold current according to the current of the reference detecting body 4.

The discriminating part 54 compares the current output by each of the plurality of the liquid surface detecting bodies 3 with the threshold current to determine whether or not there is the liquid source (M) at the liquid surface detecting point (P). In this embodiment, the threshold current set based on the current value output by the reference detecting body 4 is compared with the current output by each of the liquid surface detecting bodies 3, and if the currents output by all of the liquid surface detecting bodies 3 are greater than or equal to the threshold current, the discriminating part 54 determines that the liquid surface of the liquid source (M) exists at the upper limit of the liquid surface. More specifically, the discriminating part 54 performs an AND operation on the results of the comparison of the current values output by each of the liquid surface detecting bodies 3 and the threshold current, and determines that the liquid surface of the liquid source (M) exists at the upper limit of the liquid surface as being the set height only when all of the results of the determination are the same.

The abnormality diagnosing part 55 specifies the liquid surface detecting body 3 that is experiencing abnormality based on the currents output by the plurality of the liquid surface detecting bodies 3. For example, in case that the current value output by one of the liquid surface detecting bodies 3 is different from the current value output by the other liquid surface detecting body 3 by more than a predetermined value, the abnormality diagnosing part 55 determines that the liquid surface detecting body 3 is experiencing abnormality. Alternatively, in case that only the current value output by one of the liquid surface detecting bodies 3 exceeds the threshold current and the current value output by the other liquid surface detecting body 3 is less than the threshold current, the abnormality diagnosing part 55 determines that the liquid surface detecting body 3 is subjected to droplets or the like due to boiling of the liquid source (M) so that the liquid surface detecting body 3 is in a state of being unable to conduct a correct determination.

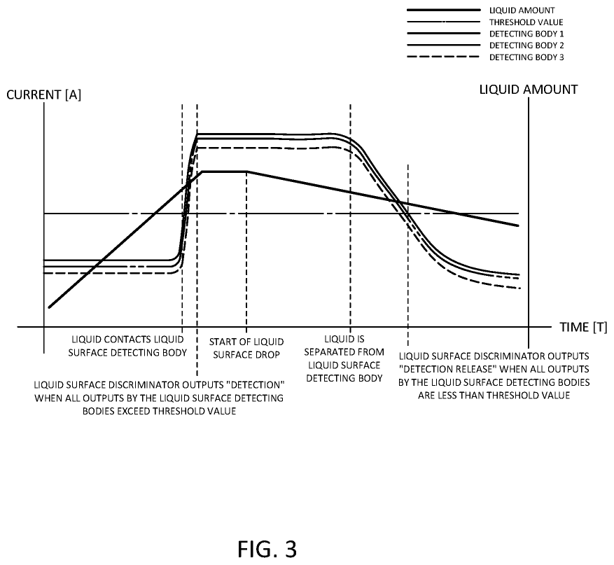

An example of determining whether or not the liquid surface of the liquid source (M) in the tank 1 exists at the upper limit of the liquid surface by the liquid source vaporization apparatus 100 having the above-mentioned configuration will be explained with reference to FIG. 3 through FIG. 5.

FIG. 3 shows a judgment of the liquid surface when the temperature or the pressure in the tank 1 is kept constant. As shown in FIG. 3, when the liquid amount of the liquid source (M) in the tank 1 increases and each of the liquid surface detecting bodies 3 makes contact with the liquid source (M), the current value output by each of the liquid surface detecting bodies 3 starts to increase. The discriminating part 54 discriminates that the liquid surface of the liquid source (M) exists at the upper limit of the liquid surface from a time when all of the current values output by each of the liquid surface detecting bodies 3 exceed the threshold current. In addition, when the liquid surface of the liquid source (M) in the tank 1 decreases and the liquid source (M) is separated from each of the liquid surface detecting bodies 3, the current value output by each of the liquid surface detecting bodies 3 decreases. The discriminating part 54 determines that the liquid surface of the liquid source (M) does not exist at the upper limit of the liquid surface in case that the current values output by all of the liquid surface detecting bodies 3 are lower than the threshold current. In either case, the discriminating part 54 changes the discriminating status only when the results of the comparison between the current values of all of the liquid surface detecting bodies 3 and the threshold current are the same.

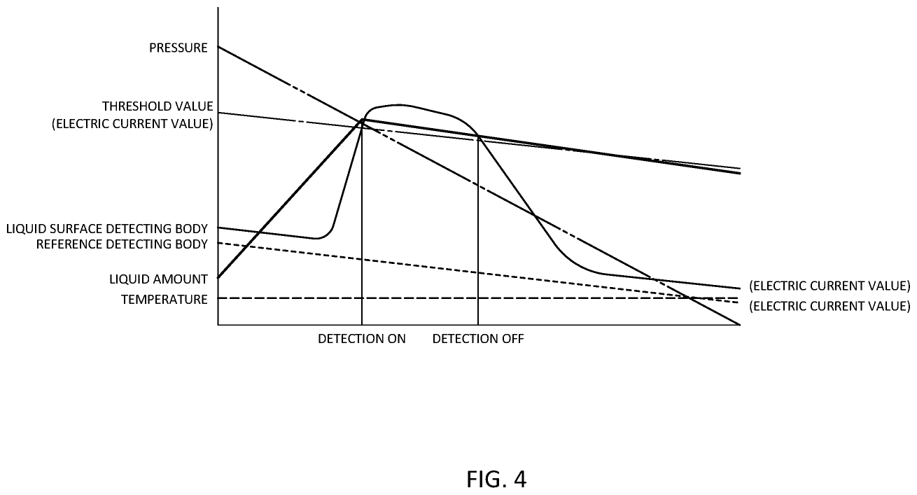

In addition, in case that the pressure in the tank 1 changes as shown in FIG. 4, the current outputs by the reference detecting body 4 and the liquid surface detecting bodies 3 also change in accordance with the pressure. Concretely, the larger the pressure is, the larger the current values output by the reference detecting body 4 and the liquid surface detecting bodies 3 are. The threshold current setting part 53 corrects the threshold current to be larger as the current value output by the reference detecting body 4 become larger so that the threshold current does not cause a false reading due to the pressure changes.

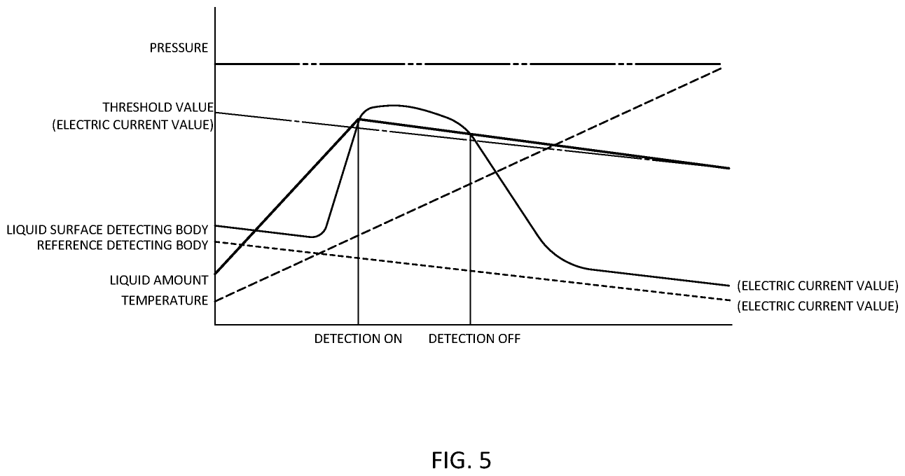

Similarly, as shown in FIG. 5, in case that the temperature in the tank 1 changes, the current values output by the reference detecting body 4 and the liquid surface detecting bodies 3 will also change in response to the temperature. Concretely, the higher the temperature is, the lower the current values output by the reference detecting body 4 and the liquid surface detecting bodies 3 will be. Similarly, the threshold current setting part 53 sets the threshold current to a higher value as the current output by the reference detecting body 4 increases so as not to occur a misjudgment due to the temperature change.

In accordance with the liquid source vaporization apparatus 100 of this embodiment, since it is so configured that the liquid surface of the liquid source (M) is discriminated to be at the upper limit of the liquid surface only when all results of the comparison between the currents output by a plurality of the liquid surface detecting bodies 3 whose liquid surface detecting points (P) are aligned at the same height and the threshold current are the same, it is possible to avoid a misjudgment that the liquid source (M) is at the upper limit of the liquid surface even if the liquid source (M) is boiling due to the heating of the heater 2, jumps up and adheres to one of the liquid surface detecting bodies 3 in a state that the liquid surface of the liquid source (M) is at a position lower than the upper limit of the liquid surface.

In addition, since the reference detecting body 4 of this embodiment is arranged above each of the liquid surface detecting bodies 3 in the tank 1 and is so configured that droplets of liquid source (M) do not adhere thereto, it is possible to correct only an effect of the pressure or the temperature in the tank 1 on the threshold current set based on the current output by the reference detecting body 4. Consequently, it is possible to set a criterion that discriminates the liquid surface according to the pressure or the temperature in the tank 1 while ensuring that the incorrect threshold current is not set due to boiling of the liquid source (M).

In addition, it is possible to also diagnose which one of the liquid surface detecting bodies 3 is experiencing an abnormality by comparing the outputs of a plurality of the liquid surface detecting bodies 3.

The other embodiment will be described.

A number of the liquid surface detecting body is not limited to three, and may be two or further more. In addition, the shape or the arrangement of the liquid surface detecting body is not limited to those described in the above-mentioned embodiment. For example, in case that the liquid surface detecting body is in a form of a rod, the liquid surface detecting point may not be the tip of the rod-shaped liquid surface detecting body but the side portion thereof, and the liquid surface detecting body may be arranged to extend horizontally in the tank. Similarly, a rod-shaped reference detecting body may be provided so as to extend horizontally above the liquid surface detecting bodies.

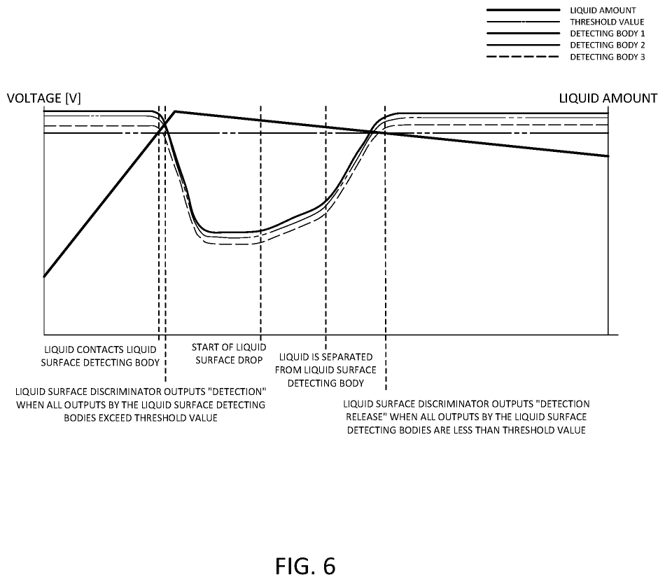

The liquid surface discriminator is so configured to detect whether or not there is the liquid surface of the liquid source at the upper limit of the liquid surface based on the current output by the liquid surface detecting bodies and the reference detecting body, however, the liquid surface discriminator may be so configured to measure an electrical resistance of the liquid surface detecting bodies and the reference detecting body and to make a decision based on the change in the electrical resistance. In this case, the electric resistance changes in the opposite direction for each current change shown in FIG. 3 through FIG. 5. Therefore, in case that the electrical resistance of each of the liquid surface detecting bodies is lower than a threshold resistance value, the liquid surface discriminator may be so configured to detect the liquid surface exists at the upper limit of the liquid surface. Similarly, the liquid surface discriminator may be so configured to detect the liquid surface based on a voltage applied to each of the liquid surface detecting bodies. Concretely, the liquid surface discriminator may comprise a constant current circuit that applies a predetermined constant current to each of the liquid surface detecting bodies and the reference detecting body, a voltage measurement mechanism that measures voltages output by each of the liquid surface detecting bodies and the reference detecting body, a threshold voltage setting part that sets a threshold voltage based on the voltage output by the reference detecting body, and a discriminating part that discriminates whether or not there is the liquid source at the set height by comparing the threshold voltage with the voltages output by each of the liquid surface detecting bodies. In case of the configuration for determining the height of the liquid surface of the liquid source based on the voltage, and in case that each of the liquid surface detecting bodies is in contact with the liquid source as shown in a graph in FIG. 6, the voltage necessary to keep the current at constant is lowered as the electrical resistance is lowered. Therefore, the discriminator may be so configured to discriminate that the liquid surface exists at the set height in case that all of the voltages output by each of the liquid surface detecting bodies are below the threshold voltage.

In addition to the liquid surface detecting mechanism described in the abovementioned embodiment, an auxiliary detecting mechanism may be further provided in the tank to detect the liquid surface using a different principle. For example, a level switch or the like may be provided in the tank as the auxiliary detecting mechanism to further reduce false detection by duplicating the detection of the liquid surface.

In case that the liquid surface detecting points of a plurality of liquid surface detecting bodies vary within a predetermined height range on the basis of the set height, the reference detecting body may be arranged at both an upper side and an outside of the predetermined height range. In accordance with this arrangement, it is possible to ensure reliability for setting the threshold value by preventing droplets of the liquid source from adhering to the reference detecting body even in situations where droplets of the liquid source may adhere to either of the liquid surface detecting bodies.

The embodiment may be modified variously or a part of each of the embodiments may be combined without departing from a spirit of this invention.

### LIST OF REFERENCE CHARACTERS

100 . . . Liquid source vaporization apparatus
1 . . . tank
2 . . . heater
3 . . . liquid surface detecting body
4 . . . reference detecting body
5 . . . liquid surface discriminator
51 . . . constant voltage circuit
52 . . . current measurement mechanism
53 . . . threshold current setting part
54 . . . discriminating part
55 . . . abnormality diagnosing part

1. A liquid source vaporization apparatus comprising
a tank inside of which a liquid source is stored,
a heater that applies heat to the liquid source in the tank,
a plurality of liquid surface detecting bodies each of whose liquid surface detecting points is arranged in a predetermined height range in the tank with a set height regarded as the reference,
a reference detecting body arranged above the predetermined height range in the tank, and
a liquid surface discriminator that discriminates whether or not there is the liquid source at the set height on a basis of a threshold value set based on a change in electrical resistance of the reference detecting body and a change in electrical resistance of a plurality of the liquid surface detecting bodies.

2. The liquid source vaporization apparatus described in claim 1, wherein
the liquid surface discriminator comprises
a constant voltage circuit that applies a constant voltage to each of the plurality of the liquid surface detecting bodies and the reference detecting body respectively,
a current measurement mechanism that measures each of currents output by the plurality of the liquid surface detecting bodies and a current of the reference detecting body respectively,
a threshold current setting part that sets a threshold current on a basis of the current output by the reference detecting body, and
a discriminating part that discriminates whether or not there is the liquid source at the set height by comparing each of the currents output by the plurality of the liquid surface detecting bodies with the threshold current.

3. The liquid source vaporization apparatus described in claim 2, wherein
the discriminating part discriminates that there is the liquid surface of the liquid source at the set height in case that all of the currents output by the plurality of the liquid surface detecting bodies exceed the threshold current.

4. The liquid source vaporization apparatus described in claim 2, wherein
the threshold current setting part sets the threshold current so as to be set that the bigger the current output by the reference detecting body is, the bigger the threshold current value is.

5. The liquid source vaporization apparatus described in claim 2, wherein
the liquid surface detecting points of the plurality of the liquid surface detecting bodies are set at the same height in the tank, and further comprising
an abnormality diagnosing part that specifies the liquid surface detecting body that is experiencing an abnormality on a basis of the currents output by the plurality of the liquid surface detecting bodies.

6. The liquid source vaporization apparatus described in claim 1, wherein
the liquid surface discriminator comprises
a constant current circuit that applies a constant current to each of the plurality of the liquid surface detecting bodies and the reference detecting body respectively,
a voltage measurement mechanism that measures each of voltages output by the plurality of the liquid surface detecting bodies and a voltage of the reference detecting body respectively,
a threshold voltage setting part that sets a threshold voltage on a basis of the voltage output by the reference detecting body, and
a discriminating part that discriminates whether or not there is the liquid source at the set height by comparing each of the voltages output by the plurality of the liquid surface detecting bodies with the threshold voltage.
